(19) United States
(12) Patent Application Publication
(10) Pub. No.: US 2011/0233561 A1
(43) Pub. Date: Sep. 29, 2011

(54) SEMICONDUCTOR SUBSTRATE

(75) Inventors: Taro NISHIGUCHI, Itami-shi (JP); Makoto Sasaki, Itami-shi (JP); Shin Harada, Osaka-shi (JP); Kyoko Okita, Itami-shi (JP); Hiroki Inoue, Itami-shi (JP); Yasuo Namikawa, Itami-shi (JP)

(73) Assignee: SUMITOMO ELECTRIC INDUSTRIES, LTD., Osaka-shi (JP)

(21) Appl. No.: 13/073,385

(22) Filed: Mar. 28, 2011

(30) Foreign Application Priority Data
Mar. 29, 2010 (JP) 2010-075719

(51) Int. Cl. H01L 29/161

(52) U.S. Cl. 257/77; 257/E29.084

(57) ABSTRACT

A supporting portion is made of silicon carbide. At least one layer has first and second surfaces. The first surface is supported by the supporting portion. The at least one layer has first and second regions. The first region is made of silicon carbide of a single-crystal structure. The second region is made of graphite. The second surface has a surface formed by the first region. The first surface has a surface formed by the first region, and a surface formed by the second region. In this way, a semiconductor substrate can be provided which has a region made of silicon carbide having a single-crystal structure and a supporting portion made of silicon carbide and allows for reduced electric resistance of an interface therebetween.

### BACKGROUND OF THE INVENTION

1. Field of the Invention

The present invention relates to a semiconductor substrate, in particular, a semiconductor substrate including a region made of silicon carbide having a single-crystal structure.

2. Description of the Background Art

In recent years, SiC (silicon carbide) substrates have been adopted as semiconductor substrates for use in manufacturing semiconductor devices. SiC has a band gap larger than that of Si (silicon), which has been used more commonly. Hence, a semiconductor device employing a SiC substrate advantageously has a large reverse breakdown voltage, low on-resistance, and properties less likely to decrease in a high temperature environment.

In order to efficiently manufacture such semiconductor devices, the substrates need to be large in size to some extent. According to U.S. Pat. No. 7,314,520, a SiC substrate of 76 mm (3 inches) or greater can be manufactured.

Industrially, the size of a SiC single-crystal substrate is still limited to approximately 100 mm (4 inches). Accordingly, semiconductor devices cannot be efficiently manufactured using large single-crystal substrates, disadvantageously. This disadvantage becomes particularly serious in the case of using a property of a plane other than the (0001) plane in SiC of hexagonal system. Hereinafter, this will be described.

A SiC single-crystal substrate small in defect is usually manufactured by slicing a SiC ingot obtained by growth in the (0001) plane, which is less likely to cause stacking fault. Hence, a single-crystal substrate having a plane orientation other than the (0001) plane is obtained by slicing the ingot not in parallel with its grown surface. This makes it difficult to sufficiently secure the size of the single-crystal substrate, or many portions in the ingot cannot be used effectively. For this reason, it is particularly difficult to effectively manufacture a semiconductor device that employs a plane other than the (0001) plane of SiC.

Instead of increasing the size of such a SiC single-crystal substrate with difficulty, it is considered to use a silicon carbide substrate having a supporting portion and a plurality of small single-crystal SiC layers connected thereonto. Each of the single-crystal SiC layers may be at least larger than the size of a chip of a semiconductor device to be manufactured. The size of this silicon carbide semiconductor substrate can be increased by increasing the number of single-crystal SiC layers as required. However, the inventors of the present application have found that when the supporting portion and the single-crystal SiC are connected to each other, electric resistance may become high at an interface therebetween.

### SUMMARY OF THE INVENTION

The present invention has been made in view of the above-described problem, and its object is to provide a semiconductor substrate, which has a region made of SiC having a single-crystal structure and a supporting portion made of silicon carbide and allows for reduced electric resistance at an interface therebetween.

A semiconductor substrate according to the present invention includes a supporting portion and at least one layer. The supporting portion is made of silicon carbide. The at least one layer has first and second surfaces. The first surface is supported by the supporting portion. The second surface is opposite to the first surface. The at least one layer has first and second regions. The first region is made of silicon carbide of a single-crystal structure. The second region is made of graphite. The second surface has a surface formed by the first region. The first surface has a surface formed by the first region and a surface formed by the second region.

According to the present invention, the first surface of the at least one layer has the surface formed by the first region, and the surface formed by the second region. In other words, the first surface has the surface made of silicon carbide, and a surface made of graphite. Since the first surface has the surface made of silicon carbide, the first surface is firmly connected to the supporting portion, which is also made of silicon carbide. Moreover, the first surface has the surface made of graphite, i.e., surface having a low resistivity, thereby reducing electric resistance at an interface between the first surface and the supporting portion. In other words, according to the present invention, the at least one layer and the supporting portion can be firmly connected to each other while reducing the electric resistance at the interface therebetween.

Preferably, the first region has a dislocation density lower than that of the supporting portion. Accordingly, the second surface formed by the first region can be improved in crystal quality. Thus, on such a second surface, an epitaxial layer of higher quality can be formed.

Preferably, the supporting portion has an impurity concentration higher than that of the first region. Accordingly, resistivity of the supporting portion can be reduced.

Preferably, the at least one layer includes a plurality of layers, which are disposed at different locations when viewed in a plan view. Accordingly, the semiconductor substrate can have a larger area.

Preferably, the first surface has an off angle of not less than 50° and not more than 65° relative to a {0001 } plane. Further, preferably, the first surface has a plane orientation of a {03-38} plane.

As apparent from the description above, the present invention can provide a semiconductor substrate which has a region made of SiC having a single-crystal structure and a supporting portion made of silicon carbide, and allows for reduced electric resistance at an interface therebetween.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a configuration of a semiconductor substrate in a first embodiment of the present invention.

FIG. 2 is a schematic cross sectional view taken along a line II-II in FIG. 1.

FIG. 3 is an enlarged view of a portion of FIG. 2.

FIGS. 4-7 are respective cross sectional views schematically showing a first to fourth steps of the method for manufacturing the semiconductor substrate in the first embodiment of the present invention.

FIG. 8 is an enlarged view of a portion of FIG. 7.

FIG. 9 is a partial cross sectional view schematically showing a direction of mass transfer resulting from sublimation, in a fifth step of the method for manufacturing the semiconductor substrate in the first embodiment of the present invention.

FIG. 10 is a partial cross sectional view schematically showing a direction of the transfer of the gap caused by the sublimation in the step corresponding to FIG. 9,

FIG. 11 is a partial cross sectional view schematically showing a direction of transfer of voids resulting from sublimation, in a sixth step of the method for manufacturing the semiconductor substrate in the first embodiment of the present invention.

FIG. 12 is a partial cross sectional view schematically showing a configuration of a semiconductor device in a second embodiment of the present invention.

FIG. 13 is a schematic flowchart showing a method for manufacturing the semiconductor device in the second embodiment of the present invention.

FIGS. 14-17 are respective partial cross sectional views schematically showing first to fourth steps of the method for manufacturing the semiconductor device in the second embodiment of the present invention.

### DESCRIPTION OF THE PREFERRED EMBODIMENTS

The following describes an embodiment of the present invention with reference to figures.

### First Embodiment

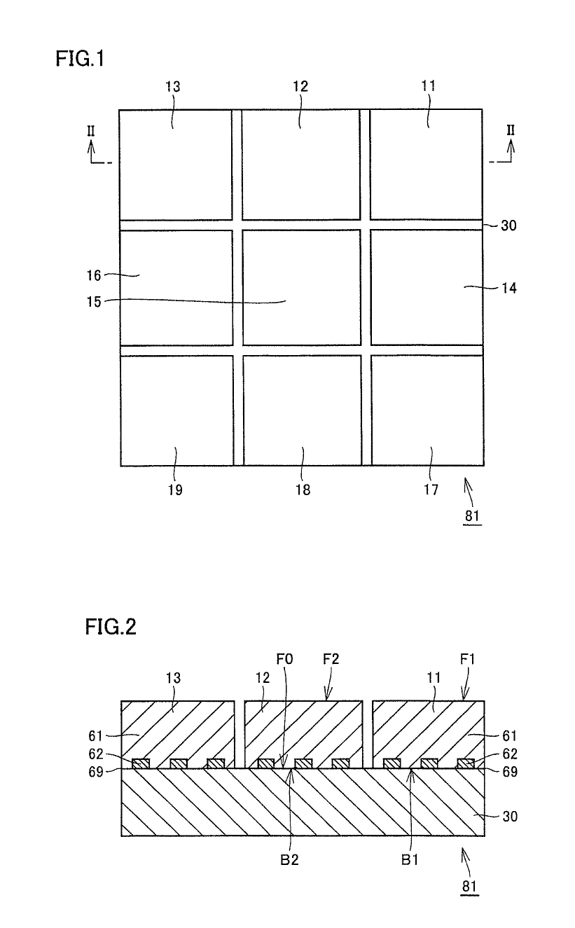

Referring to FIG. 1-FIG. 3, first, a silicon carbide substrate 81 (semiconductor substrate) of the present embodiment will be described schematically, Silicon carbide substrate 81 has a supporting portion 30, and single-crystal substrates 11-19 (layer). Supporting portion 30 is made of SiC and has a main surface F0. Each of single-crystal substrates 11-19 has a SiC region 61 as its main region, and further includes graphite regions 62 at its portions of the surface that faces main surface F0 of supporting portion 30. Each of graphite regions 62 has a small resistivity, thereby reducing resistance at an interface between each of single-crystal substrates 11-19 and supporting portion 30.

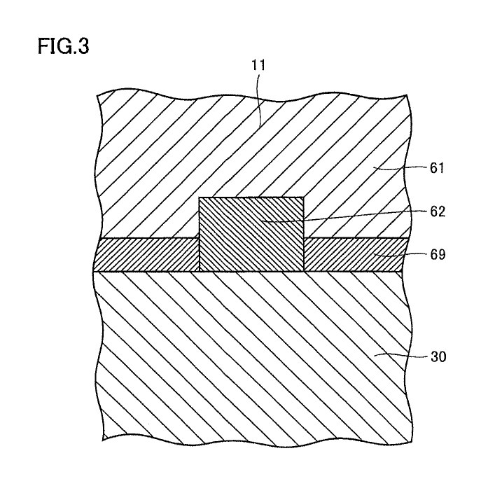

The following describes a configuration of silicon carbide substrate 81 in detail. Silicon carbide substrate 81 preferably has a certain thickness (size in the vertical direction in FIG. 2) to facilitate handling thereof in a process of manufacturing semiconductor devices using silicon carbide substrate 81. For example, silicon carbide substrate 81 preferably has a thickness of 300 μm or greater. Further, silicon carbide substrate 81 has, for example, a square planar shape with sides of 60 mm.

Each of single-crystal substrates 11-19 is mainly formed of SiC, and they are arranged in the form of matrix as shown in FIG. 1. Each of single-crystal substrates 11-19 has a backside surface (first surface) and a front-side surface (second surface) opposite to each other. For example, single-crystal substrate 11 has a backside surface B1 and a front-side surface F1, and single-crystal substrate 12 has a backside surface B2 and a front-side surface F2. The backside surface of each of single-crystal substrates 11-19 is supported by main surface F0 of supporting portion 30 and is connected to main surface F0.

Further, each of single-crystal substrates 11-19 has SiC region 61 (first region) and graphite regions 62 (second region). SiC region 61 is formed of SiC having a single-crystal structure, whereas each of graphite regions 62 is formed of graphite. Each of the front-side surfaces (for example, front-side surfaces F1 and F2) of single-crystal substrates 11-19 has a surface formed by SiC region 61.

Each of the backside surfaces (for example, backside surfaces B1 and B2) of single-crystal substrates 11-19 has a surface formed by SiC region 61 and surfaces formed by graphite regions 62. On the backside surface of each of single-crystal substrates 11-19, SiC region 61 has a high resistance layer 69. Specifically, SiC region 61 has high resistance layer 69, which is a portion particularly high in resistivity therein, at an interface with supporting portion 30. Reasons why the resistivity is particularly high at the region of high resistance layer 69 in each of single-crystal substrates 11-19 are as follows. That is, this region is formed of SiC, which has a resistivity higher than that of graphite. In addition, this region has many defects because this region is located on the interface with supporting portion 30.

Preferably, each of single-crystal substrates 11-19 has a hexagonal crystal structure, more preferably, has an off angle of not less than 50° and not more than 65° relative to the {0001} plane, and further preferably has a plane orientation of {03-38}. However, {0001}, {11-20}, or {1-100} can be also employed as a preferable plane orientation. Further, there can be employed a plane that is off by several degrees relative to each of the above-described plane orientations. Of various polytypes of the hexagonal crystal, polytype 4H is particularly preferable.

SiC region 61 of each of single-crystal substrates 11-19 has a planar shape of 20×20 mm, a thickness of 300 μm, 4H polytype, a plane orientation of {03-38}, an n type impurity concentration of 1×10¹⁹ cm⁻³, a resistivity of 5 mΩ·cm, a micro pipe density of 0.2 cm⁻², and a stacking fault density of less than 1 cm⁻¹, for example. Each graphite region 62 in single-crystal substrates 11-19 has a resistivity of 1 mΩ·cm, for example. Graphite regions 62 are formed on the backside surfaces of single-crystal substrates 11-19 at a substantially regular interval therebetween. The interval is preferably determined depending on a process of manufacturing semiconductor devices using silicon carbide substrate 81. Normally, chips are formed on a plurality of regions on one silicon carbide substrate 81, which is then cut to obtain individual chips, thereby producing a plurality of semiconductor devices. Graphite regions 62 are formed at an interval at which the plurality of regions are disposed or at an interval smaller than the interval. In this way, at least one graphite region 62 can be provided in each semiconductor device. For example, graphite regions 62 are formed at an interval of less than 2 mm.

Supporting portion 30 may have any of single-crystal, polycrystal, and amorphous crystal structures, but preferably has a crystal structure similar to those of single-crystal substrates 11-19. However, generally, an amount of defect in supporting portion 30 may be greater than those in single-crystal substrates 11-19. Since the requirement of the amount of defect is not so strict for supporting portion 30, the impurity concentration in supporting portion 30 can be readily increased as compared with those in single-crystal substrates 11-19. In addition, supporting portion 30 larger than each of single-crystal substrates 11-19 can be fabricated readily. Supporting portion 30 has a planar shape of 60×60 mm, a thickness of 300 μm, 4H polytype, a plane orientation of {03-38}, an n type impurity concentration of 1×10²⁰ cm⁻³, a micro pipe density of 1×10⁴ cm⁻², and a stacking fault density of 1×10⁵ cm⁻¹, for example.

The following describes a method for manufacturing silicon carbide substrate 81. For ease of description, only a part of single-crystal substrates 11-19 may be explained, but each of single-crystal substrates 13-19 is handled in a similar manner.

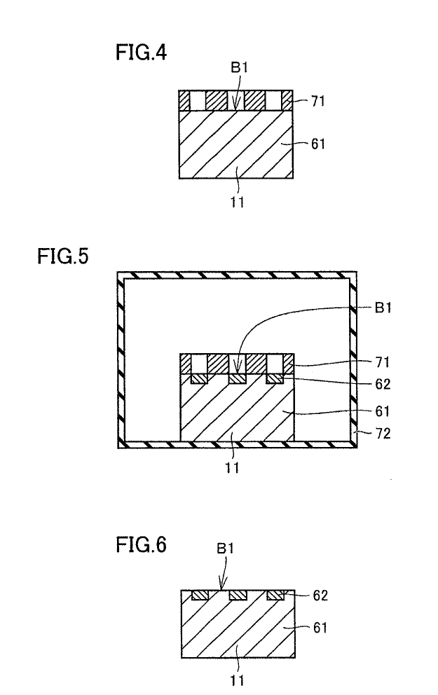

Referring to FIG. 4, first, single-crystal substrate 11 constituted by SiC region 61 is prepared. Then, a mask 71 having openings is formed on backside surface B1 of single-crystal substrate 11.

Referring to FIG. 5, with the openings of mask 71 being exposed, single-crystal substrate 11 is brought into a heating furnace 72. Then, a temperature in heating furnace 72 is increased to a temperature at which Si atoms can be desorbed from the front-side surface of SiC region 61. Accordingly, graphite regions 62 each having a desired thickness are formed on backside surface B1 of single-crystal substrate 11 at the portions exposed by the openings of mask 71. For example, graphite regions 62 each having a thickness of approximately 10 μm is formed when the temperature in heating furnace 72 is set at 2200° C., the pressure therein is set at 10 kPa, and the heat time is set at 10 minutes.

Further, referring to FIG. 6, mask 71 is removed, thereby forming single-crystal substrate 11 having backside surface B1 thus provided with graphite regions 62.

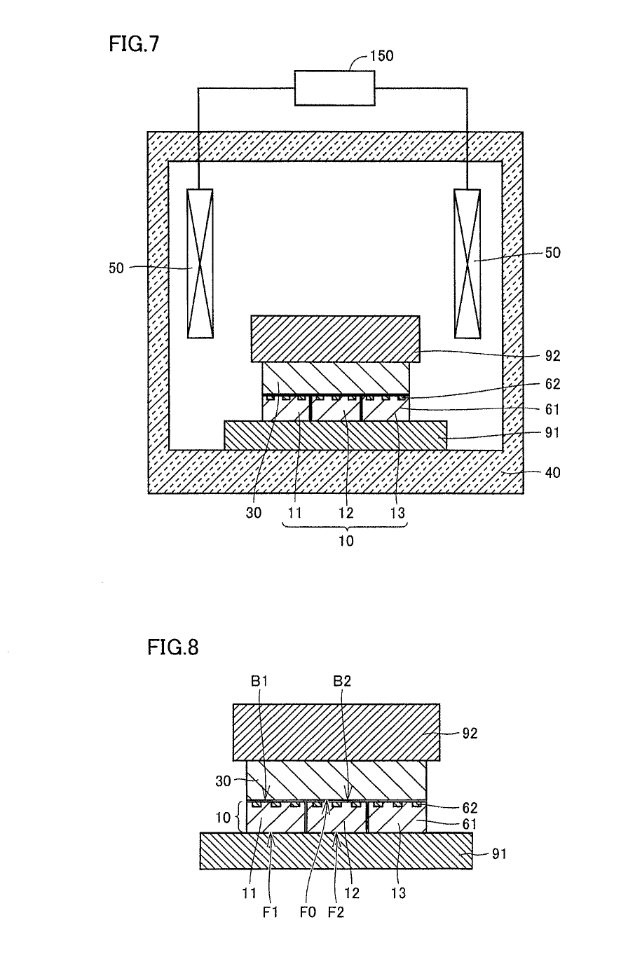

Referring to FIG. 7, supporting portion 30 is prepared. This preparation is accomplished by, for example, slicing an ingot formed of SiC so as to obtain a SiC plate, in other words, by providing the ingot with main surface F0. Supporting portion 30 may have any crystal structure of a single-crystal structure, a polycrystal structure, and an amorphous structure. Further, as the material of supporting portion 30, either of a material formed by crystal growth and a material formed by sintering can be used. Supporting portion 30 has a main surface F0 having a square shape of approximately 60 mm×60 mm, and has a thickness of 300 μm, for example.

Referring to FIG. 7 and FIG. 8, single-crystal substrates such as single-crystal substrates 11 and 12 (hereinafter, also referred to as “single-crystal substrate group 10”) and a heating device are prepared. The heating device has first and second heating members 91, 92, a heat insulation container 40, heaters 50, and a heater power source 150. Heat insulation container 40 is formed of a highly thermally insulating material. Each of heaters 50 is, for example, an electric resistance heater. First and second heating members 91, 92 have a function of absorbing heat emitted from heaters 50 and emitting the absorbed heat so as heat supporting portion 30 and single-crystal substrate group 10. Each of first and second heating members 91, 92 is formed of, for example, graphite with a small porosity.

Next, first heating member 91, single-crystal substrate group 10, supporting portion 30, and second heating member 92 are arranged to be stacked on one another in this order. Specifically, first, single-crystal substrates 11-19 (FIG. 1) are arranged on first heating member 91 in the form of a matrix. Next, single-crystal substrate group 10 and supporting portion 30 are stacked on each other so as to bring main surface F0 of supporting portion 30 into contact with the backside surface of each one in single-crystal substrate group 10. Then, second heating member 92 is placed on supporting portion 30. Then, first heating member 91, single-crystal substrate group 10, supporting portion 30, and second heating member 92 thus stacked on one another are accommodated in heat insulation container 40 having heaters 50 provided therein.

Then, the atmosphere of heat insulation container 40 is adapted to be an inert gas. An exemplary inert gas usable is a noble gas such as He or Ar; a nitrogen gas; or a mixed gas of the noble gas and nitrogen gas. Further, the pressure in heat insulation container 40 is preferably 50 kPa or smaller, and is more preferably 10 kPa or smaller.

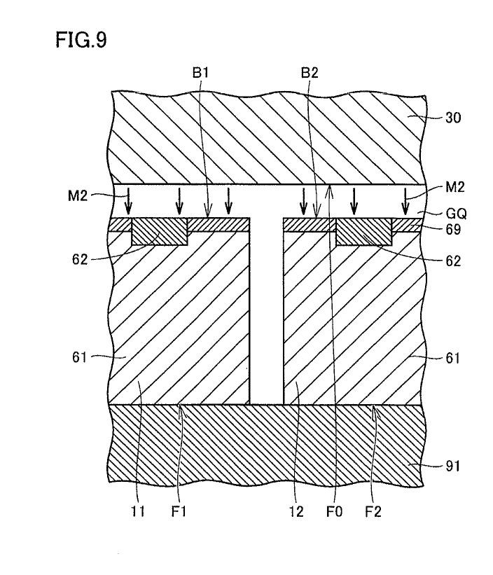

Referring to FIG. 9, at this point of time, main surface F0 of supporting portion 30 is merely placed on backside surfaces B1 and B2 of single-crystal substrates 11 and 12, and has not been connected thereto yet. Hence, when viewed microscopically, there is a minute gap GQ between each of backside surfaces B1 and B2 and main surface F0.

Next, heaters 50 heat supporting portion 30 and single-crystal substrate group 10 including single-crystal substrates 11 and 12, by means of first and second heating members 91, 92. This heating is performed such that the temperature of supporting portion 30 exceeds the sublimation temperature of SiC and the temperature of each one in single-crystal substrate group 10 becomes less than the temperature of supporting portion 30. Namely, a temperature gradient is formed such that temperature is decreased from above to below in FIG. 9. The temperature gradient is set at, preferably, not less than 1° C./cm and not more than 200° C./cm, more preferably, not less than 10° C./cm and not more than 50° C./cm between supporting portion 30 and each of single-crystal substrates 11 and 12. When the temperature gradient is thus provided in the direction of thickness (vertical direction in FIG. 9), the temperature of each of single-crystal substrates 11 and 12 is lower than the temperature of supporting portion 30 in a region in which each of single-crystal substrates 11 and 12 and supporting portion 30 are separated from each other by gap GQ. As a result, sublimation reaction of SiC is more likely to take place from supporting portion 30, as compared with single-crystal substrates 11 and 12, into gap GQ. On the other hand, recrystallization reaction resulting from the supply of the SiC material from gap GQ is more likely to take place on single-crystal substrates 11 and 12 as compared with on supporting portion 30. As a result, in gap GQ, mass transfer takes place due to the sublimation as indicated by arrows M2 in the figure.

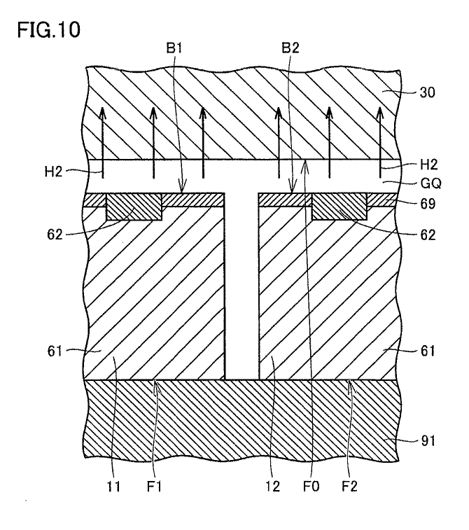

Conversely, the mass transfer indicated by arrows M2 of FIG. 9 corresponds to transfer of the space in gap GQ as indicated by arrows H2 (FIG. 10). As this transfer develops, supporting portion 30 and each of single-crystal substrates 11 and 12 are connected to each other. Further, as this transfer develops, supporting portion 30 originally prepared is gradually replaced with a supporting portion reformed by regrowth thereof on backside surfaces B1 and B2 of single-crystal substrates 11 and 12. This replacement develops gradually from its region close to each of single-crystal substrates 11 and 12,

By the regrowth, supporting portion 30 is changed to have a crystal structure corresponding to the crystal structure of each of backside surfaces B1 and B2 of single-crystal substrates 11 and 12. Further, the space corresponding to gap GQ (FIG. 10) becomes voids VD (FIG. 11) in supporting portion 30. As the heating continues, each void VD is transferred further away from main surface F0 as indicated by arrows H3 (FIG. 11). This further increases strength in connection therebetween. Moreover, in supporting portion 30, portions corresponding to the crystal structures of backside surfaces B1 and B2 become larger. Accordingly, silicon carbide substrate 81 (FIG. 2) is obtained.

According to the present embodiment, the plurality of single-crystal substrates 11-19 (FIG. 1) are combined into one by supporting portion 30, thereby obtaining an larger area of silicon carbide substrate 81 than that in the case where each of single-crystal substrates 11-19 is used solely. Thus, semiconductor devices can be manufactured more efficiently using silicon carbide substrate 81.

Further, according to the present embodiment, the backside surface of each of the single-crystal substrates (for example, single-crystal substrates 11 and 12: FIG. 2) has the surface formed by SiC region 61 and the surfaces formed by graphite regions 62. That is, each of the backside surfaces (for example, backside surfaces B1 and B2: FIG. 2) has a surface made of SiC and surfaces made of graphite.

Because each of backside surfaces B1 and B2 has the surface made of SiC, each of backside surfaces B1 and B2 is firmly connected to supporting portion 30, which is also made of SiC, In other words, in each of backside surfaces B1 and B2, the surface made of SiC are connected thereto more firmly as compared with the surfaces made of graphite.

Further, because each of backside surfaces B1 and B2 has the surfaces made of graphite, i.e., surfaces having a low resistivity, electric resistance is reduced at an interface between each of backside surfaces B1 and B2 and supporting portion 30. Specifically, for example, a current path between single-crystal substrate 11 and supporting portion 30 extends mainly through graphite regions 62 having a relatively small resistivity, thus reducing an influence of high resistance layer 69 (FIG. 3), which has a relatively large resistivity. Further, in the present embodiment, graphite regions 62 are formed by desorbing Si atoms from single-crystal SiC by means of heating. Each of graphite regions 62 obtained in this way has a small crystal defect, and therefore has a small resistivity. Accordingly, the above-described effect of reducing the electric resistance is further improved.

Namely, according to the present embodiment, the single-crystal substrates (for example, single-crystal substrates 11 and 12: FIG. 2) and supporting portion 30 are firmly connected to one another while reducing the electric resistance at the interface therebetween.

Preferably, each of SiC regions 61 (FIG. 2) has a dislocation density lower than that of supporting portion 30. Accordingly, the front-side surfaces (for example, front-side surfaces F1 and F2: FIG. 2) formed by the SiC regions can be improved in quality. Hence, on each of such front-side surfaces, an epitaxial layer of higher quality can be formed.

Preferably, the impurity concentration in supporting portion 30 (FIG. 2) is higher than that in each SiC region 61. Accordingly, the electric resistivity of supporting portion 30 can be reduced.

Preferably, each of single-crystal substrates 11-19 (FIG. 1) has a crystal structure of polytype 4H. Accordingly, silicon carbide substrate 81 suitable for manufacturing of a power semiconductor is obtained.

Preferably, in order to prevent cracks of silicon carbide substrate 81, a difference is adapted to be as small as possible between the thermal expansion coefficient of supporting portion 30 in silicon carbide substrate 81 and the thermal expansion coefficient of each of single-crystal substrates 11-19. Accordingly, cracks and warpage of silicon carbide substrate 81 can be suppressed.

Preferably, supporting portion 30 (FIG. 7) has an electric resistivity of less than 50 mΩ·cm, more preferably, less than 10 mΩ·cm.

Preferably, the impurity concentration in supporting portion 30 of silicon carbide substrate 81 (FIG. 2) is not less than 5×10¹⁸ cm⁻³, more preferably, not less than 1×10²⁰ cm⁻³. By using such a silicon carbide substrate 81 to manufacture a vertical type semiconductor device in which an electric current flows in the vertical direction such as a vertical type MOSFET (Metal Oxide Semiconductor Field Effect Transistor), on-resistance can be reduced in the vertical type semiconductor device.

An average value of the electric resistivity of silicon carbide substrate 81 is preferably 5 mΩ·cm or smaller, more preferably, 1 mΩ·cm or smaller.

Preferably, front-side surface F1 (FIG. 2) has an off angle of not less than 50° and not more than 65° relative to the {0001 } plane. This allows for higher channel mobility in front-side surface F1 than in the case where front-side surface F1 corresponds to the {0001 } plane. More preferably, the following first or second condition is satisfied.

In the first condition, the off orientation of front-side surface F1 forms an angle of 5° or smaller with the <1-100> direction of single-crystal substrate 11. More preferably, front-side surface F1 has an off angle of not less than −3° and not more than 5° relative to the {03-38} plane in the <1-100> direction of single-crystal substrate 11.

In the second condition, the off orientation of front-side surface F1 forms an angle of not more than 5° with the <11-20> direction of single-crystal substrate 11.

It should be noted that the “off angle of front-side surface F1 relative to the {03-38} plane in the <1-100> direction” refers to an angle formed by an orthogonal projection of a normal line of front-side surface F1 to a projection plane defined by the <1-100> direction and the <0001> direction, and a normal line of the {03-38} plane. The sign of positive value corresponds to a case where the orthogonal projection approaches in parallel with the <1-100> direction whereas the sign of negative value corresponds to a case where the orthogonal projection approaches in parallel with the <0001> direction.

Specifically, front-side surface F1 preferably has a plane orientation of the {03-38} plane. It should be noted that in the present specification, the {03-38} refers to, for example, the (03-38) plane or the (0-33-8) plane. Meanwhile, the {0001 } plane refers to, for example, the (0001) plane or the (000-1) plane.

In the description above, the preferable orientations of front-side surface F1 of single-crystal substrate 11 are exemplified. Preferably, the same applies to the orientation of the front-side surface of each of the other single-crystal substrates 12-19 (FIG. 1).

Further, supporting portion 30 of a square shape (FIG. 1) is illustrated, but the shape of the supporting portion is not limited to the square shape and may be a circular shape, for example. In this case, the supporting portion preferably has a diameter of 5 cm or greater, more preferably, 15 cm or greater.

Further, the resistive heating method employing electric resistance heaters as heaters 50 has been illustrated but another heating method can be employed, such as a high-frequency induction heating method or a lamp annealing method.

It should be noted that in the present embodiment, silicon carbide substrate 81 has the plurality of single-crystal substrates 11-19, but the present invention is not limited to this. The semiconductor substrate may have one single-crystal substrate. Further, an additional single-crystal substrate may be further formed on each of single-crystal substrates 11-19.

### Second Embodiment

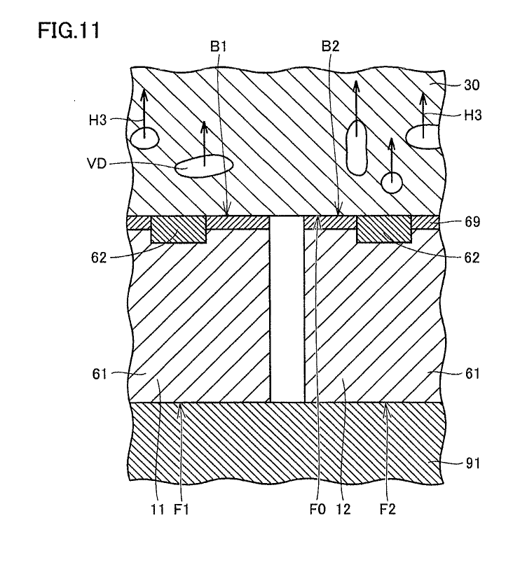

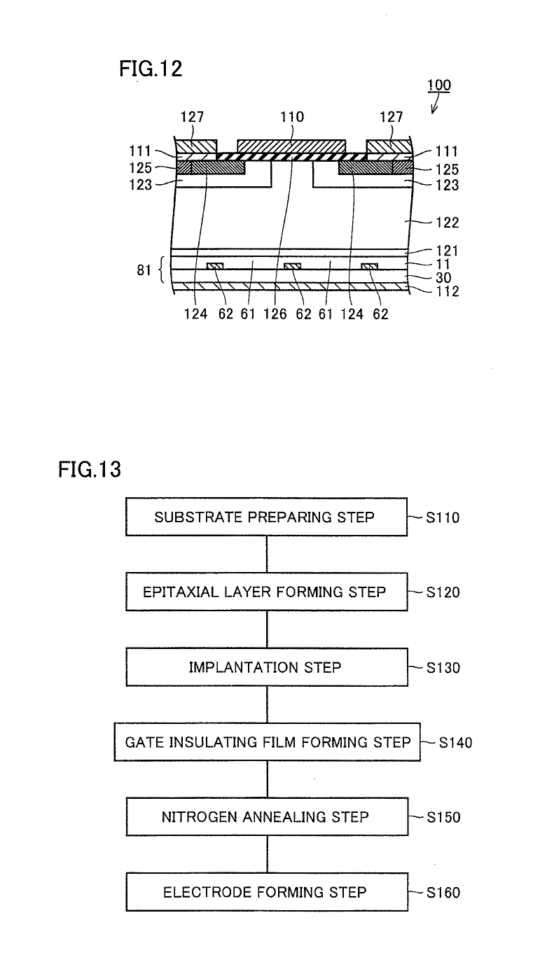

Referring to FIG. 12, a semiconductor device 100 of the present embodiment is a DiMOSFET (Double Implanted Metal Oxide Semiconductor Field Effect Transistor) of vertical type, and has silicon carbide substrate 81, a buffer layer 121, a reverse breakdown voltage holding layer 122, p regions 123, n⁺ regions 124, p⁺ regions 125, an oxide film 126, source electrodes 111, upper source electrodes 127, a gate electrode 110, and a drain electrode 112. The planar shape of semiconductor substrate 100 (shape when viewed from above in FIG. 12) is, for example, a rectangle or a square, each having sides with a length of 2 mm or greater.

In the present embodiment, silicon carbide substrate 81 has n type conductivity, and has supporting portion 30 and single-crystal substrate 11 as described in the first embodiment. SiC region 61 and one or more graphite regions 62 are provided in single-crystal substrate 11 included in one semiconductor device 100. Drain electrode 112 is provided on supporting portion 30 to interpose supporting portion 30 between drain electrode 112 and single-crystal substrate 11. Buffer layer 121 is provided on single-crystal substrate 11 to interpose single-crystal substrate 11 between buffer layer 121 and supporting portion 30.

Buffer layer 121 has n type conductivity, and has a thickness of, for example, 0.5 μm, Further, impurity with n type conductivity in buffer layer 121 has a concentration of, for example, 5×10¹⁷ cm⁻³.

Reverse breakdown voltage holding layer 122 is formed on buffer layer 121, and is made of SiC with n type conductivity. For example, reverse breakdown voltage holding layer 122 has a thickness of 10 μm, and includes a conductive impurity of n type at a concentration of 5×10¹⁵ cm⁻³.

Reverse breakdown voltage holding layer 122 has a surface in which the plurality of p regions 123 of p type conductivity are formed with spaces therebetween. In each of p regions 123, an n⁺ region 124 is formed at the surface layer of p region 123. Further, at a location adjacent to n⁺ region 124, a p⁺ region 125 is formed. An oxide film 126 is formed on reverse breakdown voltage holding layer 122 exposed between the plurality of p regions 123. Specifically, oxide film 126 is formed to extend on n⁺ region 124 in one p region 123, p region 123, an exposed portion of reverse breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed.

According to the configuration described above, a region in which carrier flow is controlled by gate electrode 110 is disposed at the side of single-crystal substrate 11 rather than the side of supporting portion 30.

The maximum value of nitrogen atom concentration is 1×10²¹ cm⁻³ or greater in a region distant away by 10 nm or shorter from the interface between oxide film 126 and each of the semiconductor layers, i.e., n⁺ regions 124, p⁺ regions 125, p regions 123, and reverse breakdown voltage holding layer 122. This achieves improved mobility particularly in a channel region below oxide film 126 (a contact portion of each p region 123 with oxide film 126 between each of n⁺ regions 124 and reverse breakdown voltage holding layer 122).

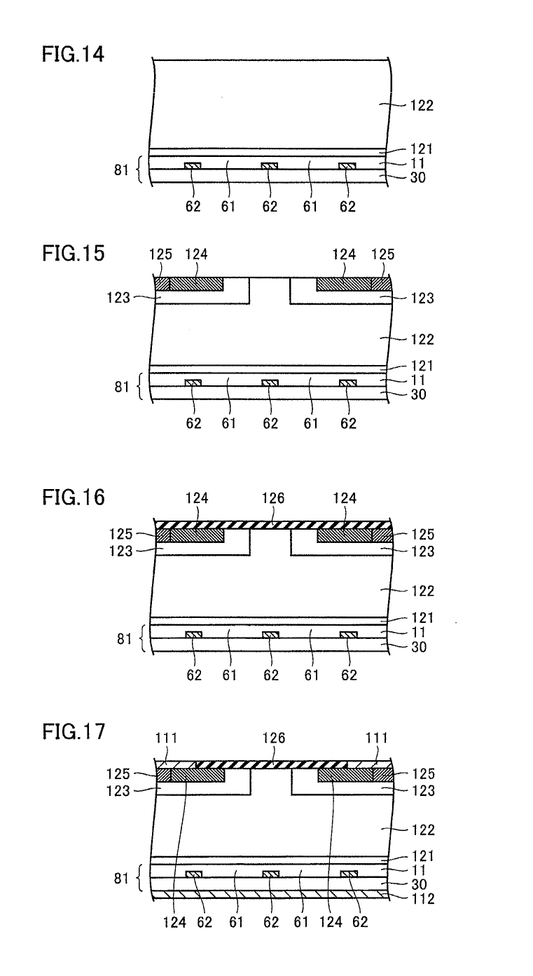

The following describes a method for manufacturing semiconductor device 100. It should be noted that FIG. 14-FIG. 17 show steps only in the vicinity of single-crystal substrate 11 of single-crystal substrates 11-19 (FIG. 1), but the same steps are performed also in the vicinity of each of single-crystal substrates 12-19.

First, in a substrate preparing step (step S110: FIG. 13), silicon carbide substrate 81 (FIG. 1 and FIG. 2) is prepared. Silicon carbide substrate 81 has n type conductivity.

Referring to FIG. 14, in an epitaxial layer forming step (step S120: FIG. 13), buffer layer 121 and reverse breakdown voltage holding layer 122 are formed as follows.

First, buffer layer 121 is formed on the front-side surface of silicon carbide substrate 81. Buffer layer 121 is made of SiC of n type conductivity, and is an epitaxial layer having a thickness of 0.5 μm, for example. Buffer layer 121 has a conductive impurity at a concentration of, for example, 5×10¹⁷ cm⁻³.

Next, reverse breakdown voltage holding layer 122 is formed on buffer layer 121. Specifically, a layer made of SiC of n type conductivity is formed using an epitaxial growth method. Reverse breakdown voltage holding layer 122 has a thickness of, for example, 10 μm. Further, reverse breakdown voltage holding layer 122 includes an impurity of n type conductivity at a concentration of, for example, 5×10¹⁵ cm⁻³.

Referring to FIG. 15, an implantation step (step S130: FIG. 13) is performed to form p regions 123, n⁺ regions 124, and p⁺ regions 125 as follows.

First, an impurity of p type conductivity is selectively implanted into portions of reverse breakdown voltage holding layer 122, thereby forming p regions 123. Then, a conductive impurity of n type is selectively implanted to predetermined regions to form n⁺ regions 124, and a conductive impurity of p type is selectively implanted into predetermined regions to form p⁺ regions 125. It should be noted that such selective implantation of the impurities is performed using a mask formed of, for example, an oxide film.

After such an implantation step, an activation annealing process is performed.

For example, the annealing is performed in argon atmosphere at a heating temperature of 1700° C. for 30 minutes.

Referring to FIG. 16, a gate insulating film forming step (step S140: FIG. 13) is performed. Specifically, oxide film 126 is formed to cover reverse breakdown voltage holding layer 122, p regions 123, n⁺ regions 124, and p⁺ regions 125. Oxide film 126 may be formed through dry oxidation (thermal oxidation). Conditions for the dry oxidation are, for example, as follows: the heating temperature is 1200° C. and the heating time is 30 minutes.

Thereafter, a nitrogen annealing step (step S150) is performed. Specifically, annealing process is performed in nitrogen monoxide (NO) atmosphere. Conditions for this process are, for example, as follows: the heating temperature is 1100° C. and the heating time is 120 minutes. As a result, nitrogen atoms are introduced into a vicinity of the interface between oxide film 126 and each of reverse breakdown voltage holding layer 122, p regions 123, n⁺ regions 124, and p⁺ regions 125.

It should be noted that after the annealing step using nitrogen monoxide, additional annealing process may be performed using argon (Ar) gas, which is an inert gas. Conditions for this process are, for example, as follows: the heating temperature is 1100° C. and the heating time is 60 minutes.

Referring to FIG. 17, an electrode forming step (step S160: FIG. 13) is performed to form source electrodes 111 and drain electrode 112 in the following manner.

First, a resist film having a pattern is formed on oxide film 126, using a photolithography method. Using the resist film as a mask, portions above n⁺ regions 124 and p⁺ regions 125 in oxide film 126 are removed by etching. In this way, openings are formed in oxide film 126. Next, in each of the openings, a conductive film is formed in contact with each of n⁺ regions 124 and p⁺ regions 125. Then, the resist film is removed, thus removing the conductive film's portions located on the resist film (lift-off). This conductive film may be a metal film, for example, may be made of nickel (Ni). As a result of the lift-off, source electrodes 111 are formed.

It should be noted that on this occasion, heat treatment for alloying is preferably performed. For example, the heat treatment is performed in atmosphere of argon (Ar) gas, which is an inert gas, at a heating temperature of 950° C. for two minutes.

Referring to FIG. 12 again, upper source electrodes 127 are formed on source electrodes 111. Further, gate electrode 110 is formed on oxide film 126. Further, drain electrode 112 is formed on the backside surface of silicon carbide substrate 81. In this way, semiconductor device 100 is obtained.

According to the present embodiment, because graphite regions 62 (FIG. 12) are provided, electric resistance can be reduced for a current path in the vertical direction, thereby reducing on resistance of semiconductor device 100 of vertical type.

It should be noted that a configuration may be employed in which conductive types are opposite to those in the present embodiment. Namely, a configuration may be employed in which p type and n type are replaced with each other. Further, the DiMOSFET of vertical type has been exemplified, but another semiconductor device may be manufactured using the semiconductor substrate of the present invention. For example, a RESURF-JFET (Reduced Surface Field-Junction Field Effect Transistor) or a Schottky diode may be manufactured.

(Appendix)

A semiconductor substrate according to the present invention includes a supporting portion and at least one layer. The supporting portion is made of silicon carbide. The at least one layer has first and second surfaces. The first surface is supported by the supporting portion. The second surface is opposite to the first surface. The at least one layer has first and second regions. The first region is made of silicon carbide of a single-crystal structure. The second region is made of graphite. The second surface has a surface formed by the first region. The first surface has a surface formed by the first region and a surface formed by the second region.

Although the present invention has been described and illustrated in detail, it is clearly understood that the same is by way of illustration and example only and is not to be taken by way of limitation, the scope of the present invention being interpreted by the terms of the appended claims

What is claimed is:

1. A semiconductor substrate comprising:
a supporting portion made of silicon carbide; and
at least one layer having a first surface supported by said supporting portion and a second surface opposite to said first surface, said at least one layer having a first region made of silicon carbide of a single-crystal structure and a second region made of graphite, said second surface having a surface formed by said first region, said first surface having a surface formed by said first region and a surface formed by said second region.

2. The semiconductor substrate according to claim 1, wherein said first region has a dislocation density lower than that of said supporting portion.

3. The semiconductor substrate according to claim 1, wherein said supporting portion has an impurity concentration higher than that of said first region.

4. The semiconductor substrate according to claim 1, wherein said at least one layer includes a plurality of layers, which are disposed at different locations when viewed in a plan view.

5. The semiconductor substrate according to claim 1, wherein said first surface has an off angle of not less than 50° and not more than 65° relative to a {0001} plane.

6. The semiconductor substrate according to claim 1, wherein said first surface has a plane orientation of a {03-38} plane.
